(19) United States
(12) Patent Application Publication
(10) Pub. No.: US 2011/0293963 A1
(43) Pub. Date: Dec. 1, 2011

(54) COATINGS, TURBINE ENGINE COMPONENTS, AND METHODS FOR COATING TURBINE ENGINE COMPONENTS

(75) Inventors: Yiping Hu, Greer, SC (US); Richard L. Bye, Morristown, NJ (US); Paul Mravcak, Simpsonville, SC (US)

(73) Assignee: HONEYWELL INTERNATIONAL INC., Morristown, NJ (US)

(21) Appl. No.: 12/787,215

(22) Filed: May 25, 2010

(51) Int. Cl. B32B 15/01; B23K 31/02; C23C 14/14; C22C 19/03; C23C 14/34

(52) U.S. Cl. 428/680; 420/455; 204/192.15; 427/597; 228/101

(57) ABSTRACT

A coating is disclosed that consists essentially of, by weight, about 27.5% to about 31.5% aluminum, about 0.20% to about 0.60% hafnium, about 0.08% to about 0.30% zirconium, about 0.005% to about 0.100% of two or more reactive elements selected from a group consisting of yttrium, lanthanum, and cerium, and a balance of nickel. Turbine engine components including the coating and methods of applying the coating on such components are also disclosed.

### TECHNICAL FIELD

The inventive subject matter generally relates to turbine engine components, and more particularly relates to coatings for turbine engine components.

### BACKGROUND

Turbine engines are used as the primary power source for various aircraft applications. Most turbine engines generally follow the same basic power generation process. Compressed air is mixed with fuel and burned, and the expanding hot combustion gases are directed against stationary turbine vanes in the engine. The vanes turn the high velocity gas flow partially sideways to impinge on the turbine blades mounted on a rotatable turbine disc. The force of the impinging gas causes the turbine rotor to spin at high speed. Jet propulsion engines use the power created by the rotating turbine rotor to draw more ambient air into the engine, and the high velocity combustion gas is passed out of the gas turbine aft end to create forward thrust. Other engines use this power to turn one or more propellers, electrical generators, or other devices.

Because turbine engines provide power for many primary and secondary functions, it is important to optimize both the engine service life and the operating efficiency. Although hotter combustion gases typically produce more efficient engine operation, the high temperatures create an environment that promotes oxidation and corrosion attack. Hence, various coatings and coating methods have been developed to increase the operating temperature limits and service lives of the high pressure turbine components, including the turbine blades and vane airfoils.

Conventional environmental protection coatings and bond coats that are applied onto the airfoil surfaces, as well as other turbine components, to provide protection against oxidation and corrosion attack include platinum-modified nickel aluminides and MCrAlY overlay coatings. Although the aforementioned coatings are effective environmental barriers for turbine components that experience high operating temperature and pressure, they may be relatively complex to form. For example, some complex coating procedures may include platinum plating and diffusion heat treatment, above-pack cementation and chemical vapor deposition aluminizing, and/or one or more diffusion heat treatments to form platinum-modified nickel aluminide. Furthermore, platinum is an expensive metal, and adding platinum to the coatings substantially increases component production costs.

Accordingly, it is desirable have an improved coating that is relatively inexpensive to produce. Additionally, it is desirable for the improved coating to provide environmental protection equal to or more effective than conventional platinum-modified aluminide coatings. Furthermore, other desirable features and characteristics of the inventive subject matter will become apparent from the subsequent detailed description of the inventive subject matter and the appended claims, taken in conjunction with the accompanying drawings and this background of the inventive subject matter.

### BRIEF SUMMARY

Coatings, turbine engine components, and methods of applying coatings are provided.

In an embodiment, by way of example only, a coating consists essentially of, by weight, about 27.5% to about 31.5% aluminum, about 0.20% to about 0.60% hafnium, about 0.08% to about 0.30% zirconium, about 0.005% to about 0.100% of two or more reactive elements selected from a group consisting of yttrium, lanthanum, and cerium, and a balance of nickel.

In another embodiment, by way of example only, a turbine engine component includes a superalloy substrate, and a coating disposed over the superalloy substrate. The coating consists essentially of a beta phase nickel aluminide and has a composition consisting essentially of, by weight about 27.5% to about 31.5% aluminum, about 0.20% to about 0.60% hafnium, about 0.08% to about 0.30% zirconium, about 0.005% to about 0.100% of two or more reactive elements selected from a group consisting of yttrium, lanthanum, and cerium, and a balance of nickel.

In still another embodiment, by way of example only, a method of forming a coating on a turbine engine component includes providing a superalloy substrate, and forming a coating over the substrate, the coating having a composition consisting essentially of, by weight about 27.5% to about 31.5% aluminum, about 0.20% to about 0.60% hafnium, about 0.08% to about 0.30% zirconium, about 0.005% to about 0.100% of two or more reactive elements selected from a group consisting of yttrium, lanthanum, and cerium, a balance of nickel.

### BRIEF DESCRIPTION OF THE DRAWINGS

The inventive subject matter will hereinafter be described in conjunction with the following drawing figures, wherein like numerals denote like elements, and

FIG. 1 is a perspective view of a turbine blade for a gas turbine engine, according to an embodiment;

FIG. 2 is a cross-sectional view of a sidewall of a turbine blade, according to an embodiment;

FIG. 3 is a cross-sectional view of a tip of a turbine blade, according to an embodiment;

FIG. 4 is a flow chart that illustrates a method of forming a bond coating and a thermal barrier coating on a turbine blade, according to an embodiment;

FIG. 5 is a flow chart that illustrates a method of forming tip coating on a turbine blade, according to another embodiment; and

FIG. 6 is a graph showing results of cyclic oxidation testing performed on three different nickel-based alloys.

### DETAILED DESCRIPTION

The following detailed description is merely exemplary in nature and is not intended to limit the inventive subject matter or the application and uses of the inventive subject matter. Furthermore, there is no intention to be bound by any theory presented in the preceding background or the following detailed description.

An improved coating is provided for use on high temperature components, such as turbine blades, nozzle guide vanes or nozzle rings. The coating is an intermetallic alloy and generally has a composition including nickel, aluminum, hafnium, zirconium, and two or more of yttrium, lanthanum, and cerium. The improved coating may be applied over various high temperature components. For example, the coating may be applied on turbine components or other high temperature components.

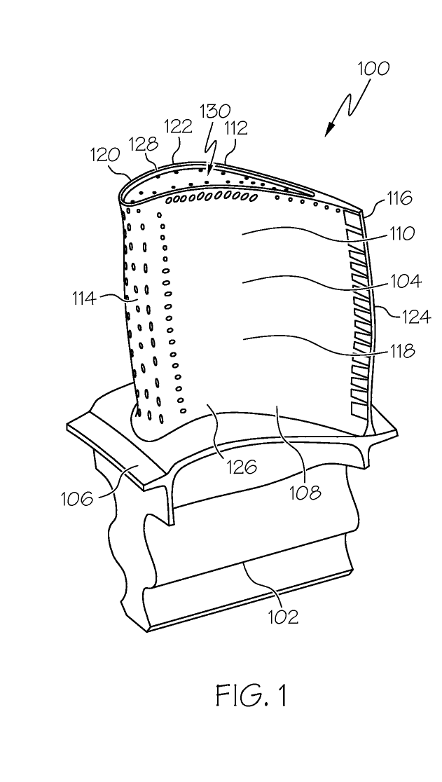

FIG. 1 is a perspective view of a blade 100 that may include the improved coating, according to an embodiment. The blade 100 may be inserted into a turbine rotor and includes a blade attachment section 102, an airfoil 104, and a platform 106. The blade attachment section 102 provides an area in which a shape is machined. In an embodiment, the shape corresponds with a shape formed in a respective blade attachment slot (not shown) of the turbine hub (e.g., hub 114 in FIG. 1). For example, in some embodiments, the shape may be a fir tree shape. In other embodiments, the shape may be a beveled shape. However, in other embodiments, any one of numerous other shapes suitable for attaching the blade 100 to the turbine may be alternatively machined therein.

The airfoil 104 has a root 108 and two outer walls 110, 112. The root 108 is attached to the platform 106 and is integrally formed with each outer wall 110, 112. The outer walls 110, 112 have outer surfaces that define an airfoil shape. The airfoil shape includes a leading edge 114, a trailing edge 116, a pressure side 118 along the first concave outer wall 110, a suction side 120 along the second convex outer wall 112, a tip 122, a pressure side discharge trailing edge slot 124, and an airfoil platform fillet 126. The tip 122 serves as a wall that extends between the concave pressure side wall 110 and the convex suction side wall 112. In an embodiment, a tip cap 128 extends from the tip 122 to form a well 130. The tip cap 128 may be configured to extend substantially parallel to the concave pressure side wall 110 and the convex suction side wall 112 beyond the tip 122 a particular height. In an example, the tip cap 128 extends an entire length of one or both of the concave pressure side wall 110 and the convex suction side wall 112. In other examples, the tip cap 128 may extend a portion of the lengths of one or both of the concave pressure side wall 110 and the convex suction side wall 112. The tip cap 128 may have height in a range of about 0.3 mm to about 1.2 mm, in an embodiment. In other embodiments, the height may be greater or less than the aforementioned range. Although depicted as substantially uniform in height, the tip cap 128 may be shorter at some locations than at others.

To provide structural integrity during exposure to extremely high temperatures (e.g., temperatures of 1100° C. or greater), the blade 100 is made of a single crystal superalloy. A “single crystal superalloy” may be defined as a superalloy with a single crystallographic orientation throughout its entirety that is substantially free of high angle boundaries. In some embodiments, an incidental amount of low angle boundaries, which are commonly defined as the boundaries between adjacent grains whose crystallographic orientation differs by less than about 5 degrees, such as tilt or twist boundaries, may be present within the single crystal superalloy after solidification and fabrication of the single crystal superalloy component. However, preferably, low angle boundaries are not present in the single crystal superalloy component.

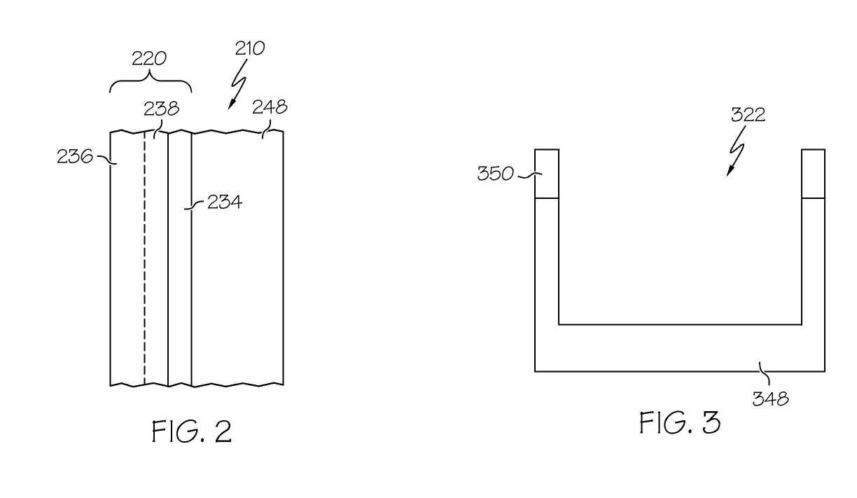

To reduce thermal fatigue resulting from prolonged exposure to the high temperatures, the improved coating alluded to above may be included as part of a coating system formed over at least a portion of the blade 100. In an embodiment, the coating system may be included on a pressure side 118, a suction side 120 as well as the platform 106 of the blade 100. For example, the coating system may be disposed over substantially an entirety of the blade 100. FIG. 2 is a cross-sectional view of a side wall 210 of a blade including a coating system 220, according to an embodiment. In an example, the coating system 220 is formulated to provide oxidation resistance properties. The coating system 220 is disposed over a base superalloy 248 and includes a bond coating 234, a thermal barrier coating 236, and one or more intermediate layers 238 (shown in phantom), in an embodiment. The base superalloy 248 may be composed of, but is not limited to, a nickel-based superalloy, in an embodiment. Suitable nickel-based superalloys include, but are not limited to, MAR-M-247EA, MAR-M-247DS, CMSX3 or SC180. In other embodiments, the base superalloy 248 may comprise a cobalt-based superalloy.

The bond coating 234 improves adherence of the thermal barrier coating 236 to the intermediate layer 238. The bond coating 234 has a thickness in a range of about 25 microns to about 100 microns, in an embodiment. In other embodiments, the bond coating 234 may be thicker or thinner than the aforementioned range. In accordance with an embodiment, the bond coating 234 comprises an intermetallic alloy composition consisting essentially of nickel, aluminum, hafnium, zirconium, and two or more reactive elements selected from a group consisting of yttrium, lanthanum, and cerium. In another embodiment, in addition to the aforementioned elements, trace elements may be present that do not have a material effect on the basic and novel characteristics of the intermetallic alloy.

According to an embodiment, the intermetallic alloy composition includes, by weight, about 27.5% to about 31.5% aluminum. Aluminum is included in the intermetallic alloy so as to interact with the nickel to thereby form beta phase nickel aluminide (NiAl). Additionally, inclusion of aluminum at relatively high amounts promotes formation of a protective alumina scale, which effectively protects turbine airfoils from severe oxidation attack and prolongs their service life. Other embodiments of the composition may include more or less aluminum than the aforementioned range.

The intermetallic alloy composition further includes about 0.20% to about 0.60% hafnium, in an embodiment. Hafnium promotes resistance to environmental damage by oxidation. In addition, hafnium can segregate to grain boundaries of thermally grown oxides (TGO) and slow down outward diffusion of aluminum. This slows down the growth rate of the TGO on the bond coating 234 which can dramatically improve the performance of the thermal barrier coating 236. Thus, in combination with the other alloying elements in the indicated ranges, the presence of hafnium promotes optimized bond coating and thermal barrier coating performance. Other embodiments of the composition may include more or less hafnium than the aforementioned range.

The intermetallic composition further includes about 0.08% to about 0.30% zirconium, in an embodiment. Zirconium is included along with hafnium to segregate to grain boundaries of thermally grown oxides to thereby slow outward diffusion of the aluminum and improve oxidation resistance of the bond coating. Other embodiments of the composition may include more or less zirconium than the aforementioned range.

In an embodiment, the nickel-based intermetallic composition further includes about 0.005% to about 0.100 of two or more reactive elements selected from a group consisting of yttrium, lanthanum, and cerium. Advantageously over non-doped reactive elements, co-doping yttrium, lanthanum, and/or cerium increases the reaction with the sulfur to form stable compounds that minimize the amount of sulfur that can migrate to a free surface of the component. Accordingly, the oxidation properties of the composition are greatly improved over those of conventional bond coating compositions. According to an embodiment, the intermetallic alloy composition includes, by weight, about 0.005% to about 0.100% yttrium, about 0.005% to about 0.100% lanthanum, and about 0.005% to about 0.100% cerium. In another embodiment, the intermetallic alloy composition includes, by weight, about 0.005% to about 0.100% yttrium and about 0.005% to about 0.100% lanthanum. In still another embodiment, the intermetallic alloy composition includes, by weight, about 0.005% to about 0.100% yttrium and about 0.005% to about 0.100% cerium. In yet another embodiment, the intermetallic alloy composition includes, by weight, about 0.005% to about 0.100% lanthanum and about 0.005% to about 0.100% cerium. Other embodiments of the composition may include more or less yttrium, lanthanum, and/or cerium than the aforementioned ranges.

To insure that the coating performs well as a bond coat for a thermal barrier coating, the bond coating 234 is formed as beta phase nickel aluminide, NiAl. In an embodiment, the coating is substantially platinum-free. In this way, the bond coating 234 is less expensive to form than conventional platinum-modified aluminide coating. Additionally, the aforementioned intermetallic alloy provides improved adherence for the thermal barrier coating 236, which results in increased service life of the thermal barrier coating 236.

The thermal barrier coating 236 protects the blade from the extremely high temperatures. Thermal barrier coating 236 may comprise, for example, a partially stabilized zirconia thermal barrier coating, such as yttria stabilized zirconia (YSZ). The thermal barrier coating 236 has a thickness in a range of about 125 microns to about 250 microns, in an embodiment. In other embodiments, the thermal barrier coating 236 may be thicker or thinner than the aforementioned range.

As alluded to above, intermediate layers 238 may be included between the bond coating 234 and the thermal barrier coating 236. The intermediate layers 238 can be formed by specifically designing the bond coating 234 to reduce the effect of impurities in the bond coating 234 and to minimize the growth of oxides on the bond coating 234. As a result, the adherence of the thermal barrier coating 236 to the bond coating 234 is improved and thermal mismatch stress due to rapid growth of oxides between the bond coating 234 and the thermal barrier coating 236 is reduced. If included, the intermediate layers 238 may comprise pure alumina modified with reactive elements, such as Hf, Zr, Y, La and Ce, and may have a thickness in a range of about 1 microns to about 5 microns, in an embodiment. In other embodiments, the intermediate layers 238 may be thicker or thinner than the aforementioned range.

In another embodiment, the improved coating may be included to reinforce a tip portion of the turbine component. For example, the improved coating may be disposed over a tip (e.g. tip 122 of FIG. 1) of the blade. FIG. 3 is a cross-sectional view of a blade tip 322, according to an embodiment. The blade tip 322 comprises a base superalloy 348 and a tip coating 350 to provide oxidation resistance to the tip 322. The blade 300 is made of the single crystal superalloy mentioned above and the tip coating 350 is disposed over the base superalloy 348, in an embodiment. The tip coating 350 is formulated substantially similar to the intermetallic alloy composition mentioned above for bond coating 234 of FIG. 2. In an embodiment, the tip coating 350 has a thickness in a range of about 50 microns to about 510 microns. In other embodiments, the tip coating 250 may be thicker or thinner than the aforementioned range.

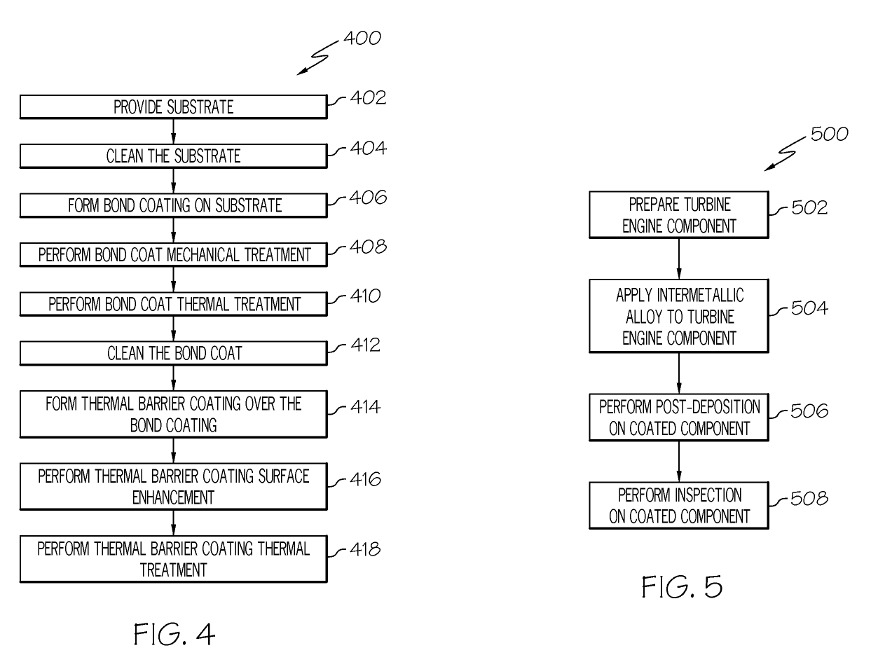

Several methods may be performed for applying the improved coating over a turbine component, such as a blade. FIG. 4 is a flow diagram of a method 400 forming a bond coating and thermal barrier coating on a turbine engine component, according to an embodiment. In an embodiment, a substrate is provided, step 402. The substrate may be a turbine blade, or any other turbine component such as, for example, a vane or a shroud, that is subjected to high gas temperatures. The substrate may comprise nickel-based superalloys, cobalt-based superalloys, and any of the other materials or material systems discussed above for fabrication of a blade.

In an embodiment, the base superalloy is cleaned, step 404, to remove any contaminants that have formed on or adhered to the surface. The cleaning may incorporate an aqueous cleaning and abrasive blast steps. The bond coating is formed on the substrate, step 406. The bond coating comprises a composition selected from the intermetallic compositions described above. In an embodiment, the selected intermetallic alloy may be deposited using various known deposition techniques such as, for example, electron beam physical vapor deposition (EB-PVD), cathodic arc deposition or direct current magnetron sputtering, and may be deposited to a thickness in the range of about 25 microns to about 100 microns. After coating formation, the deposited intermetallic coating is mechanically treated, step 408. In an embodiment, the deposited intermetallic coating is mechanically treated by a process such as peening to consolidate the coating and improve its thermal fatigue strength. Commonly used peening media such as glass bead, ceramic bead, or cut wire may be used. The selection of peening media is typically determined based on deposition technique used for the bond coating. The deposited intermetallic coating is also subjected to a thermal treatment, step 410. For example, the base superalloy with the coating is placed in a vacuum furnace or other heat treatment apparatus and exposed to a temperature in a range of about 1040° C. to about 1110° C. for a time period of about 2 hours to about 4 hours to improve bonding strength with the base superalloy and homogenize the coating's microstructure. In another embodiment, the heat treatment may occur at higher or lower temperatures for longer or shorter time periods. The bond coating may be cleaned, step 412, after thermal treatment in a manner similar to that described in step 404.

Next, a thermal barrier coating is formed over the bond coating, step 414. In one embodiment, the thermal barrier coating is yttria partially-stabilized zirconia (YSZ) that is deposited on the bond coating by plasma spraying, or electron beam physical vapor deposition (EB-PVD). A thickness of thermal barrier coating may vary according to design parameters and may be, for example, between about 100 microns and about 300 microns, and typically between about 125 microns and about 250 microns. After deposition, the thermal barrier coating may be subjected to a surface enhancement process in an effort to improve the surface smoothness of the thermal barrier coating surface, step 416. Improved surface smoothness can lead to improved aerodynamic performance and improved engine performance. Typically a thermal treatment is performed as the final step, step 418. Preferably, heat treatment occurs in a vacuum at a temperature in the range of about 1050° C. to about 1100° C. for about 2 to 4 hours. In other embodiments, the heat treatment may occur at higher or lower temperatures for shorter or longer time periods.

FIG. 5 is a flow diagram of a method 500 of forming a tip coating on a turbine engine component, according to an embodiment. In an embodiment, the turbine engine component is prepared, step 502. For example, the turbine engine component may be prepared by identifying one or more turbine engine components, such as a turbine blade, and detaching the component. In another embodiment, the turbine engine component may be a newly fabricated blade. In an embodiment, step 502 may include chemically preparing the surface of the turbine engine component at least in proximity to and/or on surfaces defining the structural feature. The identified turbine engine component may include an outer environment-protection coating, and hence, the coating may need to be removed. Thus, a chemical stripping solution may be applied to a surface of the turbine engine component, such as the surfaces and portions of the component surrounding and/or defining the structural feature. Suitable chemicals used to strip the coating may include, for example, nitric acid solution. However, other chemicals may alternatively be used, depending on a particular composition of the coating.

In another embodiment of step 502, the turbine engine component may be mechanically prepared. Examples of mechanical preparation include, for example, pre-deposition machining and/or degreasing surfaces in proximity to and/or defining the structural feature in order to remove any oxidation, dirt or other contaminants. In another embodiment, additional or different types and numbers of preparatory steps can be performed.

Next, an intermetallic alloy may be applied to the turbine engine component, step 504. In an embodiment, the intermetallic alloy has a composition that is substantially similar in formulation to the intermetallic compositions described above. The intermetallic alloy may be laser-welded onto a designated area of the turbine engine component. For example, the intermetallic alloy is laser deposited to a blade tip. According to an embodiment, the intermetallic alloy may be provided as substantially spherical powder particles, which provide improved powder flow properties and help maintain a stable powder feed rate during the welding process. The intermetallic alloy powder may be used in conjunction with a CO₂ laser, a YAG laser, a diode laser, or a fiber laser. In an embodiment, a welding process includes laser powder fusion welding, in which the intermetallic alloy is laser deposited onto the desired area to form both a desired geometry and dimension with metallurgically sound buildup. Both automatic and manual laser welding systems are widely used to perform laser powder fusion welding processes. An exemplary automatic welding repair is described in detail in U.S. Pat. No. 7,250,081 entitled “Methods For Repair Of Single Crystal Superalloys By Laser Welding And Products Thereof” and incorporated herein by reference.

In another embodiment, applying the intermetallic alloy to a desired area may include plasma transfer arc (PTA), micro plasma, and tungsten inert gas (TIG) welding methods. In still other embodiments, the step of applying the intermetallic alloy may include performing a thermal spray process such as argon-shrouded plasma spray, high velocity oxygen fuel (HVOF) or low pressure plasma spray (LPPS).

At least one post-deposition step is performed on the turbine engine component, step 506. A particular post-deposition step may depend on the type of application process that was performed in step 504. For example, the post-deposition step 506 can include additional processes that improve the mechanical properties and metallurgical integrity of the turbine engine component. Such processes may include final machining the turbine engine component to a predetermined or original design dimension and heat treatment to relieve stresses, improve bonding strength with the base superalloy and homogenize the microstructure of the deposited material.

After the post-deposition step 506 is completed, at least one inspection process can be performed, step 508. In an embodiment, the inspection process may be employed to determine whether any surface defects exist, such as cracks or other openings, step 510. The inspection process may be conducted using any well-known non-destructive inspection techniques including, but not limited to, a fluorescent penetration inspection, and a radiographic inspection. If an inspection process indicates that a surface defect exists, the process may return to either steps 502, 504, or 506. If an inspection process indicates that a surface defect does not exist, the process ends and the repaired turbine engine component may be ready to be implemented into a turbine engine or other system. After the inspection process step 506 has been completed, an environmental barrier coating and a thermal barrier coating may be deposited on the engine component.

Although the methods 400, 500 are described above as being performed on blades and/or airfoils, they alternatively may be performed on other components in which a nickel-based alloy may be beneficial.

The following examples are presented to illustrate aspects and features of various embodiments of the present inventive subject matter, and are not to be taken as limiting the inventive subject matter in any respect.

### Example 1

Cyclic oxidation testing data were obtained for a new intermetallic alloy formulated according to an embodiment described above (“HON7A”) and a 2^{nd} generation single crystal superalloys such as SC180A. Table I below provides the compositions of each alloy (wt. %).

| | HON 7A | SC180A |
|---|---|---|
| Al | 31.08 | 5.1 |
| Hf | 0.37 | 0.11 |
| Zr | 0.11 | 0.004 |
| La | 88 ppmw | |
| B | | 0.001 |
| C | | 0.002 |
| Cr | | 5.1 |
| Co | | 9.8 |
| Mo | | 1.6 |
| Nb | | <0.01 |
| Ni | Balance | Balance |
| Re | | 3.0 |
| Ta | | 8.2 |
| Ti | | 1.0 |
| W | | 4.9 |
| Y | 185 ppmw | 60 ppmw |

Each alloy was vacuum induction melted and cast into bars. The cast bars were hot isostatically pressed at a pressure of about 15 ksi at a temperature of about 1200° C. for four hours. Button samples approximately 25.4 mm in diameter by 3.1 mm in thickness were machined from the cast bars. The surfaces of the samples were sanded and wet blasted using 240 mesh silica grit. The surfaces of the samples were then ultrasonically cleaned in toluene. The samples were alternately placed in a furnace chamber maintained at 1200° C. for twenty-seven minutes, removed and cooled in moving room temperature air (e.g., between about 20° C. to about 25° C.) for three minutes for nine hundred eighty-four (984) cycles. Periodically, the samples were removed from the furnace, weighed in order to determine the weight change as a function of the number of cycles, and then returned to the furnace for continued testing.

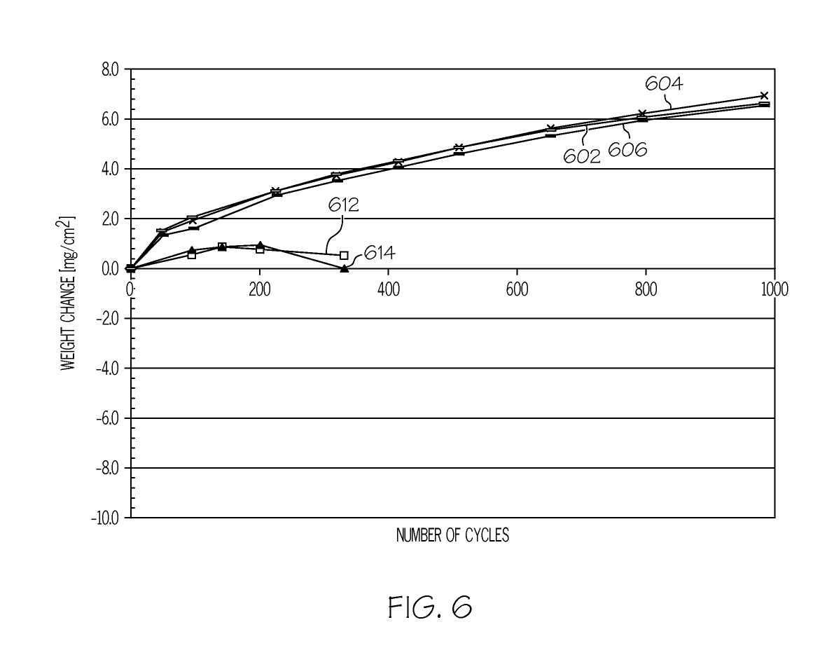

FIG. 6 is a graph showing results of the cyclic oxidation testing conducted as mentioned above. The weight change for each sample was divided by the original sample surface area and then plotted against the number of cycles conducted. Plot lines 602, 604, 606 represent the results for HON7A and lines 612, 614 represent results for SC180A. The results demonstrate that the HON7A alloy has significantly better cyclic oxidation performance than SC180A.

### Example 2

In another example, button samples approximately 25.4 mm in diameter by 3.1 mm in thickness were machined from a HON7A cast ingot. The samples were cleaned in an aqueous ultrasonic system and grit blasted using 220 grit alumina particles. A thermal barrier coating of 7YSZ was deposited onto a surface of the samples by electron beam physical vapor deposition to a thickness of about 125 microns. The thermal barrier coated samples were subjected to cyclic oxidation testing. Specifically, the samples were alternately placed in a furnace chamber maintained at 1150° C. (2100° F.) for twenty-seven minutes, removed and cooled in moving room temperature air (e.g., between about 20° C. to about 25° C.) for three minutes. Unexpectedly, the thermal barrier coatings exhibited a long thermal cycling life. The thermal barrier coating remained intact after testing for 1474 hours (e.g., 2,948 cycles).

While at least one exemplary embodiment has been presented in the foregoing detailed description of the inventive subject matter, it should be appreciated that a vast number of variations exist. It should also be appreciated that the exemplary embodiment or exemplary embodiments are only examples, and are not intended to limit the scope, applicability, or configuration of the inventive subject matter in any way. Rather, the foregoing detailed description will provide those skilled in the art with a convenient road map for implementing an exemplary embodiment of the inventive subject matter. It being understood that various changes may be made in the function and arrangement of elements described in an exemplary embodiment without departing from the scope of the inventive subject matter as set forth in the appended claims.

What is claimed is:

1. A coating for a turbine engine component, the coating having a composition consisting essentially of, by weight:
about 27.5% to about 31.5% aluminum;
about 0.20% to about 0.60% hafnium;
about 0.08% to about 0.30% zirconium;
about 0.005% to about 0.100% of two or more reactive elements selected from a group consisting of yttrium, lanthanum, and cerium; and
a balance of nickel.

2. The coating of claim 1, wherein the two or more reactive elements consist of yttrium, lanthanum, and cerium.

3. The coating of claim 1, wherein the two or more reactive elements consist of lanthanum and yttrium.

4. The coating of claim 1, wherein the coating is substantially platinum-free.

5. A turbine engine component, comprising:
a substrate comprising a superalloy; and
a coating disposed over the substrate, the coating consisting essentially of a beta phase nickel aluminide and having a composition consisting essentially of, by weight:
about 27.5% to about 31.5% aluminum;
about 0.20% to about 0.60% hafnium;
about 0.08% to about 0.30% zirconium;
about 0.005% to about 0.100% of two or more reactive elements selected from a group consisting of yttrium, lanthanum, and cerium; and
a balance of nickel.

6. The turbine engine component of claim 5, wherein the coating consists of yttrium, lanthanum, and cerium.

7. The turbine engine component of claim 5, wherein the coating consists of lanthanum and yttrium.

8. The turbine engine component of claim 5, wherein the coating is substantially platinum-free.

9. The turbine engine component of claim 5, wherein:
the coating serves as a bond coating; and
a thermal barrier coating is disposed over the coating.

10. The turbine engine component of claim 9, wherein the thermal barrier coating comprises yttria partially-stabilized zirconia.

11. The turbine engine component of claim 9, wherein the coating has a thickness in a range of about 25 microns to about 100 microns.

12. The turbine engine component of claim 5, further comprising an airfoil having a tip, wherein the coating is disposed over the tip.

13. The turbine engine component of claim 12, wherein the coating has a thickness in a range of about 50 microns to about 510 microns.

14. A method of forming a coating on a turbine engine component, the method comprising:
providing a substrate comprising a superalloy; and
forming a coating over the substrate, the coating having a composition consisting essentially of, by weight:
about 27.5% to about 31.5% aluminum;
about 0.20% to about 0.60% hafnium;
about 0.08% to about 0.30% zirconium;
about 0.005% to about 0.100% of two or more reactive elements selected from a group consisting of yttrium, lanthanum, and cerium; and
a balance of nickel.

15. The method of claim 14, wherein the step of forming comprises depositing the coating over the substrate.

16. The method of claim 15, wherein the step of depositing comprises electron beam physical vapor depositing the coating over the substrate.

17. The method of claim 15, wherein the step of depositing comprises sputtering the coating onto the substrate.

18. The method of claim 14, wherein the step of forming comprises welding the coating onto the substrate.

19. The method of claim 14, further comprising forming a thermal barrier coating over the bond coating.

20. The method of claim 19, wherein the composition is substantially platinum-free.
